(19) United States
(12) Patent Application Publication
(10) Pub. No.: US 2017/0328951 A1
(43) Pub. Date: Nov. 16, 2017

(54) EMBEDDED BUILT-IN SELF-TEST (BIST) CIRCUITRY FOR DIGITAL SIGNAL PROCESSOR (DSP) VALIDATION

(71) Applicant: Altera Corporation, San Jose, CA (US)

(72) Inventor: Weng Hong Liew, Sungkai (MY)

(21) Appl. No.: 15/154,266

(22) Filed: May 13, 2016

(51) Int. Cl. G01R 31/3177; G11C 8/04

(52) U.S. Cl. CPC G01R 31/3177; G11C 8/04

(57) ABSTRACT

Programmable integrated circuits with specialized processing blocks such as digital signal processing (DSP) blocks are provided. Each DSP block may include embedded built-in self-test circuitry implemented using existing input registers and output registers in the DSP blocks. The input registers may be selectively coupled in a loop to serve as a linear feedback shift register (LFSR). The output registers may be selectively coupled in a chain to serve as a multiple input signature register (MISR).

Configured in this way, the LIFR and the MISR circuits of the DSP blocks are not implemented using soft logic and can therefore easily meet performance criteria.

### BACKGROUND

This invention relates to testing integrated circuits and more particularly, to testing integrated circuit using built-in self-test circuitry.

Consider a configurable device such as a programmable logic device (PLD) as one example of an integrated circuit. As applications for which configurable devices are used increase in complexity, it has become more common to include specialized processing blocks in configurable devices. Such types of specialized processing blocks—commonly referred to as digital signal processing blocks or DSP blocks—may include a concentration of circuitry that has been partly or fully hardwired to perform one or more specific tasks, such as a logical or a mathematical operation.

To ensure satisfactory operation of an integrated circuit that contains DSP blocks, the DSP blocks are generally tested during debug and design operations. Testing may also be performed during manufacturing.

It can be cumbersome to perform high-speed testing using only external test equipment. It is therefore often desirable to include internal test support circuitry on an integrated circuit to facilitate testing of the specialized processing blocks. Because the internal test circuitry is incorporated into the integrated circuit that is to be tested, this type of test circuitry is sometimes referred to as built-in self-test (BIST) circuitry.

Conventionally, performance validation using BIST circuitry has involved using available soft logic resource on a programmable logic device to form a linear feedback shift register at the input of a DSP block and a multiple input signature register at the output of the DSP block. Implemented using soft logic, the linear feedback shift register and the multiple input signature register present two additional logic circuits per DSP block that need to be modeled and verified during the integrated circuit design flow. The timing analysis that has to be performed on these two circuits can be fairly time consuming and is highly dependent on the timing model accuracy, which has become more unpredictable at smaller process nodes.

It is within this context that the embodiments described herein arise.

### SUMMARY

This relates generally to integrated circuits and more particularly, to integrated circuits with built-in self-test (BIST) circuitry. In accordance with some embodiments, a programmable integrated circuit die may be provided with programmable soft logic, configuration memory circuitry, and specialized processing blocks sometimes referred to as digital signal processing (DSP) blocks. In particular, a DSP block may include embedded BIST circuitry that is not implemented using soft logic.

The embedded DSP BIST circuitry may be implemented using existing input registers and output registers within the DSP block. The input registers may be selectively enabled to operate as a linear feedback shift register (LFSR), whereas the output registers may be selectively enabled to operate as a multiple input signature register (MISR). The input registers may be placed in an LFSR mode by selectively asserting a first enable signal, whereas the output registers may be placed in an MISR mode by selectively asserting a second enable signal. The LFSR can include multiple multiplexers and a logic XOR gate coupled to the input registers in a loop. The MISR can include multiple logic XOR gates and multiplexers coupled in a chain.

To perform validation on the DSP block, a seed BIST value may be fed into the input registers while the first enable signal is deasserted. After latching the seed value, both the first and second enable signals may be simultaneously asserted. After assertion of the first and second enable signals, the BIST circuitry may wait for a predetermined number of clock cycles before comparing a signature generated by the output registers with a pre-computed signature. If the signatures match, the operating frequency of the DSP block can be increased and validation continues. If the signatures are mismatched, validation is complete.

Further features of the invention, its nature and various advantages will be more apparent from the accompanying drawings and following detailed description.

### BRIEF DESCRIPTION OF THE DRAWINGS

FIG. 1 is a diagram of an illustrative programmable integrated circuit in accordance with an embodiment.

FIG. 2 is a diagram of a digital signal processing block with a separate test pattern generator and a separate output response analyzer that are implemented using soft logic.

FIG. 3A is a diagram of an illustrative specialized processing block with embedded selectively enabled linear feedback shift register (LFSR) circuit and multiple input signature register (MISR) circuit in accordance with an embodiment.

FIG. 3B is a circuit diagram of a selectively enabled linear feedback shift register circuit implemented using input registers within a specialized processing block in accordance with an embodiment.

FIG. 3C is a circuit diagram of a selectively enabled multiple input signature register circuit implemented using output registers within a specialized processing block in accordance with an embodiment.

FIG. 4 is a diagram of an integrated circuit design system that may be used to design integrated circuits in accordance with an embodiment.

FIG. 5 is a diagram of illustrative computer-aided design (CAD) tools that may be used in a circuit design system in accordance with an embodiment.

FIG. 6 is a flow chart of illustrative steps for designing an integrated circuit in accordance with an embodiment.

FIG. 7 is a flow chart of illustrative steps for performing validation on a specialized processing block with embedded built-in self-test circuitry in accordance with an embodiment.

### DETAILED DESCRIPTION

Embodiments of the present invention relate to integrated circuits and more particularly, to ways of providing built-in self-test optimization on programmable integrated circuits.

As described above in the Background section, conventional methods for performing built-in self-test operations for digital signal processing (DSP) blocks in a programmable integrated circuit typically rely on using soft logic to implement an additional linear feedback shift register and an additional multiple input shift register for each DSP block. The timing analysis that needs to be performed on these additional register circuits can be invariably time consuming.

In accordance with an embodiment, programmable integrated circuits may be provided with specialized processing blocks having embedded built-in self-test (BIST) circuitry that is not implemented using soft logic. In particular, the embedded BIST circuitry may leverage any existing input and output registers within each specialized processing block and can be selectively enabled to perform BIST functions during validation or selectively bypassed during normal user modes. The embedded BIST circuitry within each specialized processing blocks is specifically designed to have sufficient performance to carry out any desired functionality of that specialized processing block, so the time previously needed to ensure/verify BIST performance can be greatly reduced.

It will be recognized by one skilled in the art, that the present exemplary embodiments may be practiced without some or all of these specific details. In other instances, well-known operations have not been described in detail in order not to unnecessarily obscure the present embodiments.

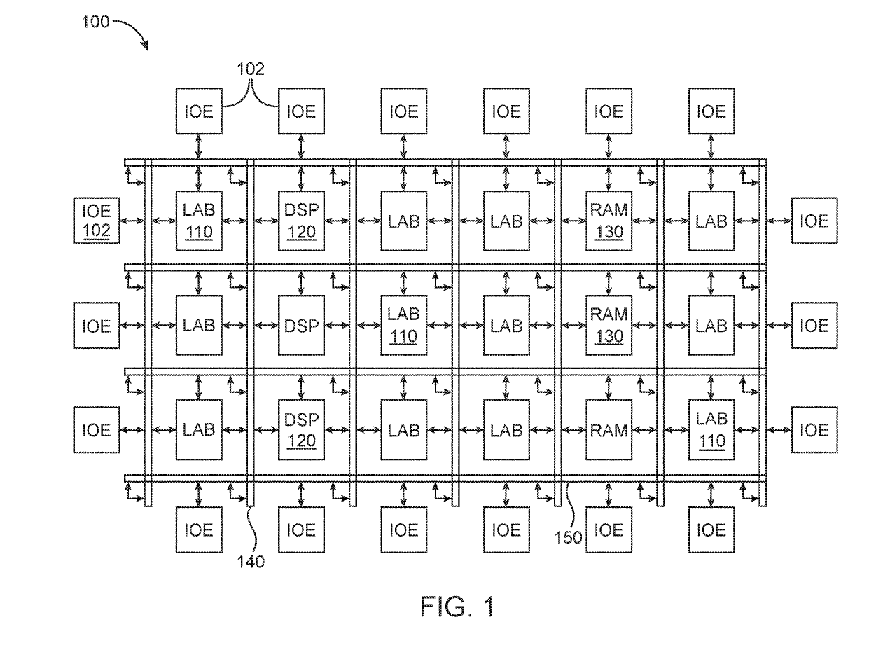

An illustrative embodiment of a programmable integrated circuit such as programmable logic device (PLD) 100 that may be configured to implement a circuit design is shown in FIG. 1. As shown in FIG. 1, the programmable logic device (PLD) may include a two-dimensional array of functional blocks, including logic array blocks (LABs) 110 and other functional blocks, such as random access memory (RAM) blocks 130 and digital signal processing (DSP) blocks 120, for example. Functional blocks such as LABs 110 may include smaller programmable regions (e.g., logic elements, configurable logic blocks, or adaptive logic modules) that receive input signals and perform custom functions on the input signals to produce output signals.

Programmable logic device 100 may contain programmable memory elements. Memory elements may be loaded with configuration data (also called programming data) using input-output elements (I0Es) 102. Once loaded, the memory elements each provide a corresponding static control signal that controls the operation of an associated functional block (e.g., LABs 110, DSP 120, RAM 130, or input-output elements 102).

In a typical scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, etc.

The memory elements may use any suitable volatile and/or non-volatile memory structures such as random-access-memory (RAM) cells, fuses, antifuses, programmable read-only-memory memory cells, mask-programmed and laser-programmed structures, combinations of these structures, etc. Because the memory elements are loaded with configuration data during programming, the memory elements are sometimes referred to as configuration memory, configuration RAM (CRAM), or programmable memory elements.

In addition, the programmable logic device may have input-output elements (ICES) 102 for driving signals off of PLD and for receiving signals from other devices. Input-output elements 102 may include parallel input-output circuitry, serial data transceiver circuitry, differential receiver and transmitter circuitry, or other circuitry used to connect one integrated circuit to another integrated circuit.

The PLD may also include programmable interconnect circuitry in the form of vertical routing channels 140 (i.e., interconnects formed along a vertical axis of PLD 100) and horizontal routing channels 150 (i.e., interconnects formed along a horizontal axis of PLD 100), each routing channel including at least one track to route at least one wire. If desired, the interconnect circuitry may include pipeline elements, and the contents stored in these pipeline elements may be accessed during operation. For example, a programming circuit may provide read and write access to a pipeline element.

Note that other routing topologies, besides the topology of the interconnect circuitry depicted in FIG. 1, are intended to be included within the scope of the present invention. For example, the routing topology may include wires that travel diagonally or that travel horizontally and vertically along different parts of their extent as well as wires that are perpendicular to the device plane in the case of three dimensional integrated circuits, and the driver of a wire may be located at a different point than one end of a wire. The routing topology may include global wires that span substantially all of PLD 100, fractional global wires such as wires that span part of PLD 100, staggered wires of a particular length, smaller local wires, or any other suitable interconnection resource arrangement.

If desired, programmable logic device (PLD) 100 may be configured to implement a custom circuit design. For example, the configuration RAM may be programmed such that LABs 110, DSP 120, and RAM 130, programmable interconnect circuitry (i.e., vertical channels 140 and horizontal channels 150), and the input-output elements 102 form the circuit design implementation.

Digital signal processor (DSP) blocks 120—sometimes referred to as “specialized processing blocks”—may include a concentration of circuitry that has been partially or fully hardwired to perform one or more specific tasks, such as a logical or a mathematical operation. A DSP block may also contain one or more specialized structures, such as an array of configurable memory elements. Examples of structures that are commonly implemented in such DSP blocks include: multipliers, adders, accumulators, arithmetic logic units (ALUs), barrel-shifters, various memory elements (such as FIFO/LIFO/SIPO/RAM/ROM/CAM blocks and register files), logic AND/NAND/OR/NOR arrays, etc., or combinations thereof. Storage elements with a DSP may serve different purposes as configuration memory. For instance, storage elements within a DSP block may store coefficients for implementing FIR filters. Alternatively, storage elements within a DSP block may be used to pipeline a critical path or to synchronize data before it is processed.

To ensure satisfactory operation of an integrated circuit that includes DSP blocks, the DSP blocks are generally tested during debug and design operations. Testing may also be performed during manufacturing or during normal operation. Since testing using external test equipment is oftentimes infeasible, internal test circuitry is oftentimes incorporated into the integrated circuit that is to be tested; this type of test circuitry is sometimes referred to as built-in self-test (BIST) circuitry.

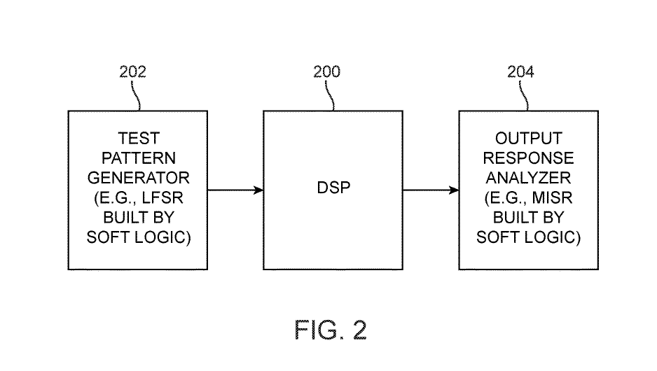

Conventional BIST architectures for testing DSP blocks are satisfactory in certain situations, but can be inefficient when scaled to handle multiple DSP blocks. A system environment of the type that may be used during test operations is shown in FIG. 2. As shown in FIG. 2, a discrete DSP block 200 is tested using associated BIST circuitry, which includes test pattern generator 202 and output response analyzer 204. Test pattern generator 202 is a linear feedback shift register (LFSR) that is built using soft reconfigurable logic on the integrated circuit and that generates test patterns for inputting to DSP block 200. Output response analyzer 204 is a multiple input signature register (MISR) that is also built using soft reconfigurable logic on the integrated circuit and that generates a unique signature based on test outputs received from DSP block 200.

As described above in the Background section, any BIST circuitry that is implemented using soft logic needs to be optimized during the integrated circuit design flow, an extra step that can be fairly time consuming. The extra time required for the timing analysis of test pattern generator 202 and output response analyzer 204 is further exacerbated for each DSP block that needs BIST circuitry. For example, if an integrated circuit includes 100 DSP blocks and if each of the 100 DSP blocks needs its own dedicated BIST circuitry (i.e., a separate instantiation of test pattern generator 202 and output response analyzer 204 for each DSP block), the overall duration of the timing analysis required to verify and close the timing of the extra BIST circuitry may be increased by more than two times, more than ten times, or more than 100 times, etc.

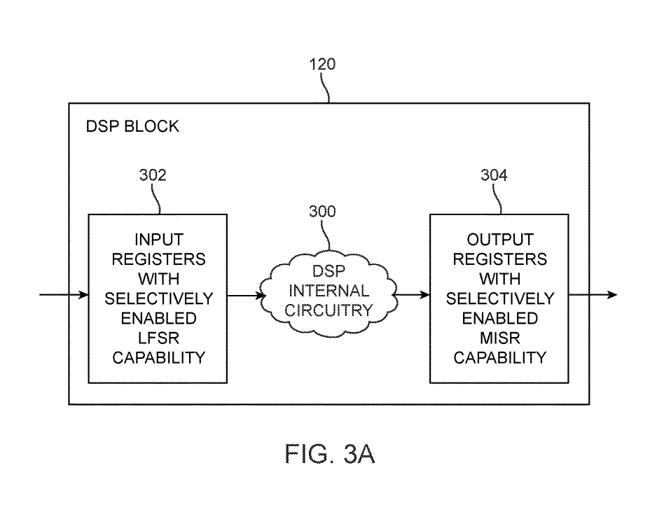

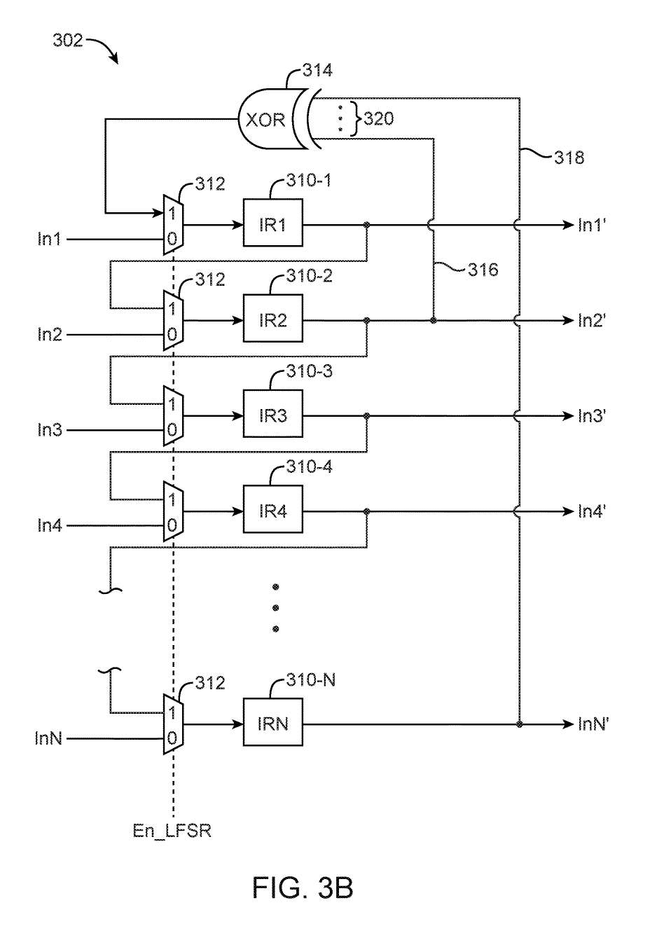

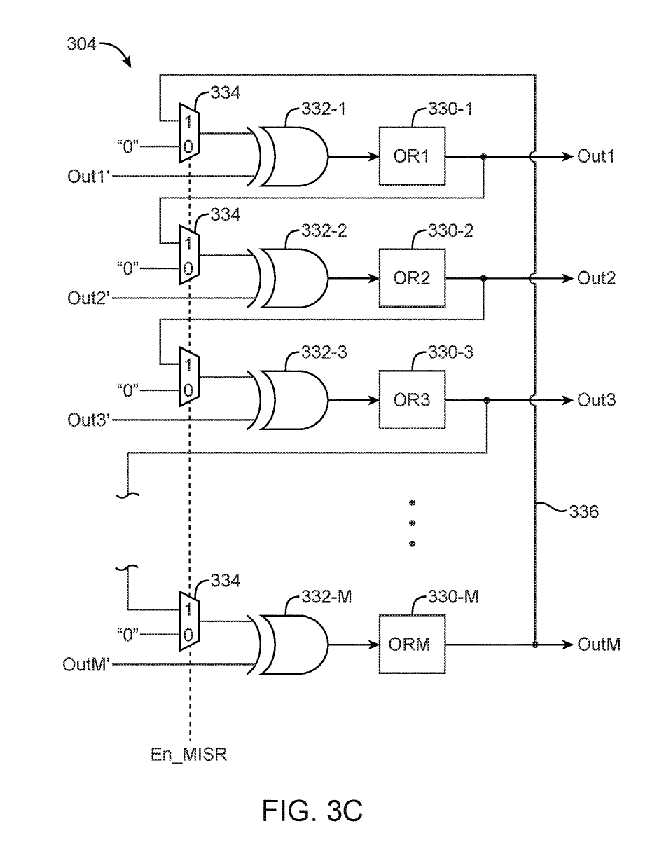

In accordance with an embodiment, the BIST circuitry may be embedded within the DSP block itself by leveraging any existing input and output registers inside the DSP block. FIG. 3A is a diagram showing a specialized processing block such as digital signal processing (DSP) block 120 may include DSP internal (core) circuitry 300 and associated input and output register circuitry. In particular, DSP block 120 may include input register circuitry such as input registers 302 that can be selectively enabled to serve as a linear feedback shift register (LFSR). Digital signal processing block 120 may also include output register circuitry such as output registers 304 that can be selectively enabled to serve as a multiple input signature register (MISR).

During normal user operation when DSP block 120 is being used to perform its specialized function(s), the LFSR and the MISR capabilities of input registers 302 and output registers 304, respectively, may be disabled (or bypassed). During a validation phase, which may occur post fabrication at the factory or may occur after the user has programed the device (i.e., before actual user operation or while the normal user operation has been temporarily suspended), input registers 302 can be configured as an input stimulus generator (e.g., by configuring input registers 302 in an LFSR mode) to generate a test pattern that is fed as an input to DSP internal circuitry 300, whereas output registers 304 can be configured as an output data compressor (e.g., by configuring output registers 304 in an MISR mode) to receive output test data from core circuitry 300 and to compress the received data into a unique signature that can be used to determine whether the DSP block 120 has passed testing.

Input registers 302 with selectively enabled LFSR capability and output registers 304 with selectively enabled MISR capability are not built using soft logic but is instead built using specifically hard-wired non-reconfigurable circuits. Configured in this way, the performance of the embedded BIST circuitry (e.g., input registers 302 and output registers 304) can be readily optimized and guaranteed without requiring lengthy time analysis operations, thereby dramatically simplifying the integrated circuit design flow.

FIG. 3B is a diagram of circuit 302 that includes DSP input registers and that can be selectively enabled as a linear feedback shift register (LFSR) circuit. As shown in FIG. 3B, circuit 302 may include input registers 310 (e.g., clock-triggered latches 310-1, 310-2, 310-3, 310-4, . . . , and 310-N), a multiplexer 312 associated with each input register 310, and a logic gate such as logic XOR (exclusive-OR) gate 314.

In the example of FIG. 3B, first input register 310-1 may be fed using first multiplexer 312, second input register 310-2 may be fed using second multiplexer 312, third input register 310-3 may be fed using third multiplexer 312, . . . , and Nth input registers 310-N may be fed using Nth multiplexer 312. First multiplexer 312 may have a first (0) input that receives external input signal In1 and a second (1) input that is coupled to the output of logic XOR gate 314. Similarly, second multiplexer 312 may have a first (0) input that receives external input signal In2 and a second (1) input that is coupled to the output of the first input register 310-1. Third multiplexer 312 may have a first (0) input that receives external input signal In3 and a second (1) input that is coupled to the output of the second input register 310-2. Input registers 310-1 may have corresponding outputs In1′, In2′, In3′, . . . , and InN′, respectively, that are fed to DSP internal circuitry 300 (FIG. 3A). Input registers 310 connected in this way are sometimes considered to be connected in series, in a chain, or in a cascaded arrangement.

Each multiplexer 312 may have a control input that receives enable signal En_LFSR. Logic XOR gate 314 may have inputs that are connected to at least some of the outputs of the input registers. In the example of FIG. 3B, gate 314 has an input that is connected to the output of second input register 310-2 via path 316 and another input that is connected to the output of the last (most significant bit) input register 310-N via path 318. These feedback connections 316 and 318 are sometimes referred to as “taps.” For example, logic XOR gate 314 may be coupled to at least two taps, at least four taps, or other suitable number of tap points (as indicated by dots 320). In general, the taps may be connected to any subset of input register outputs.

Arranged in this way, circuit 302 may be configured to operate as a linear feedback shift register whenever enable signal En_LFSR is asserted (e.g., when signal En_LFSR is driven high). During normal (non-testing) operations, enable signal En_LFSR may be deasserted (e.g., signal En_LFSR may be driven low) to bypass the LFSR loop so that input registers 310 are used to simply latch incoming parallel data bits. The LFSR loop performance should be higher than performance of the DSP internal circuitry to ensure a sufficient hold time margin.

FIG. 3C is a diagram of circuit 304 that includes DSP output registers and that can be selectively enabled as a multiple input signature register (MISR) circuit. As shown in FIG. 3C, circuit 302 may include output registers 330 (e.g., clock-triggered latches 330-1, 330-2, 330-3, 330-4, . . . , and 330-M), a multiplexer 334 associated with each output register 330, and also a logic gate such as logic XOR gate 332 associated with each output register 330.

In the example of FIG. 3C, first output register 330-1 may be fed using first XOR gate 332-1, second output register 330-2 may be fed using second XOR 332-2, third output register 330-3 may be fed using third XOR gate 332-3, . . . , and Mth output registers 330-M may be fed using Mth XOR gate 332-M. First gate 332-1 may have a first input that receives output signal Out1′ from the DSP internal circuitry and a second input that is coupled to the output of a first corresponding multiplexer 334. Similarly, second gate 332-2 may have a first input that receives output signal Out2′ from the DSP internal circuitry and a second input that is coupled to the output of a second corresponding multiplexer 334. Third gate 332-3 may have a first input that receives output signal Out3′ from the DSP internal circuitry and second input that is coupled to the output of a third corresponding multiplexer 334. Output registers 330-1 may have corresponding outputs Out1, Out2, Out3, . . . , and OutM, respectively, that serve as outputs for DSP block 120 (FIG. 3A).

Each multiplexer 334 may have a first (0) input that is connected to a ground line (e.g., the first input may receive a logic “0” value), a second (1) input that is connected to the output of a preceding output registers, and a control input that receives a MISR enable signal En_MISR. In particular, the first multiplexer 334 associated with registers 330-1 has its second input connected to the output of the MSB (most significant bit) register 330-M. Output registers 330 connected in this way are sometimes considered to be connected in series, in a chain, or in a cascaded arrangement. The number of output registers may be different than the number of input registers (i.e., M may be different than N). If desired, the number of input registers may also be equal to the number of output registers.

Arranged in this way, circuit 304 may be configured to operate as a multiple input signature register whenever enable signal En_MISR is asserted (e.g., when signal En_MISR is driven high). During normal (non-testing) operations, enable signal En_MISR may be deasserted (e.g., signal En_LFSR may be driven low) to bypass the MISR loop so that output registers 330 are used to simply latch outgoing parallel data bits. The MISR performance should be higher than performance of the DSP internal circuitry to ensure a sufficient hold time margin.

Computer-aided design (CAD) tools in a circuit design system may be used to design a programmable integrated circuit such as a programmable logic device that includes DSP blocks with embedded BIST circuitry.

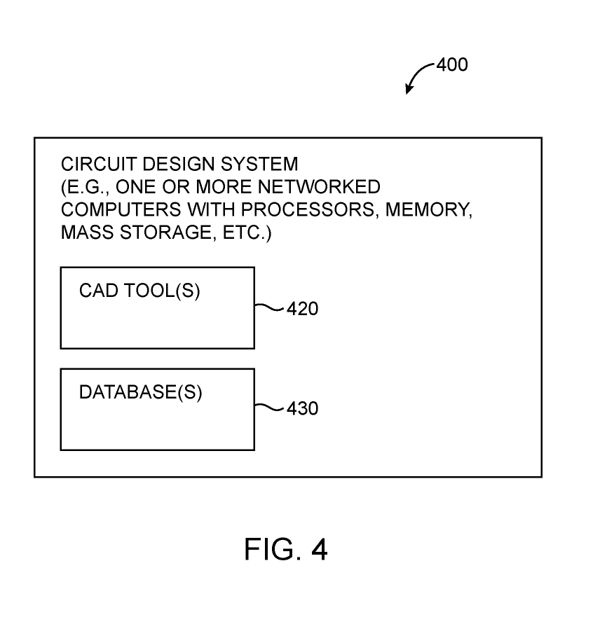

An illustrative circuit design system 400 in accordance with an embodiment is shown in FIG. 4. Circuit design system 400 may be implemented on integrated circuit design computing equipment. For example, system 400 may be based on one or more processors such as personal computers, workstations, etc. The processor(s) may be linked using a network (e.g., a local or wide area network). Memory in these computers or external memory and storage devices such as internal and/or external hard disks may be used to store instructions and data.

Software-based components such as computer-aided design tools 420 and databases 430 reside on system 400. During operation, executable software such as the software of computer aided design tools 420 runs on the processor(s) of system 400. Databases 430 are used to store data for the operation of system 400. In general, software and data may be stored on any computer-readable medium (storage) in system 400. Such storage may include computer memory chips, removable and fixed media such as hard disk drives, flash memory, compact discs (CDs), digital versatile discs (DVDs), Blu-ray discs (BDs), other optical media, and floppy diskettes, tapes, or any other suitable memory or storage device(s). When the software of system 400 is installed, the storage of system 400 has instructions and data that cause the computing equipment in system 400 to execute various methods (processes). When performing these processes, the computing equipment is configured to implement the functions of the circuit design system.

The computer aided design (CAD) tools 420, some or all of which are sometimes referred to collectively as a CAD tool, a circuit design tool, or an electronic design automation (EDA) tool, may be provided by a single vendor or by multiple vendors. Tools 420 may be provided as one or more suites of tools (e.g., a compiler suite for performing tasks associated with implementing a circuit design in a programmable logic device) and/or as one or more separate software components (tools). Database(s) 430 may include one or more databases that are accessed only by a particular tool or tools and may include one or more shared databases. Shared databases may be accessed by multiple tools. For example, a first tool may store data for a second tool in a shared database. The second tool may access the shared database to retrieve the data stored by the first tool. This allows one tool to pass information to another tool. Tools may also pass information between each other without storing information in a shared database if desired.

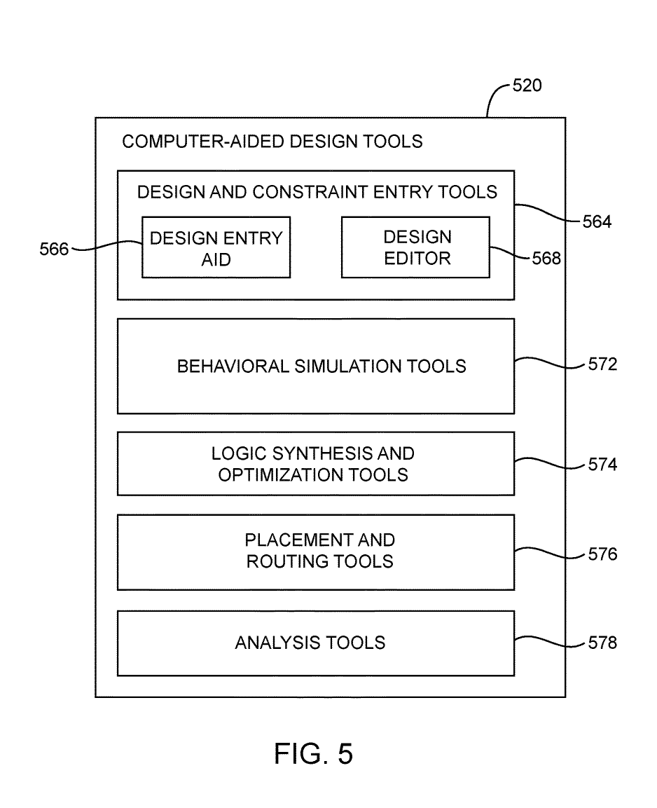

Illustrative computer aided design tools 520 that may be used in a circuit design system such as circuit design system 400 of FIG. 4 are shown in FIG. 5.

The design process may start with the formulation of functional specifications of the integrated circuit design (e.g., a functional or behavioral description of the integrated circuit design). A circuit designer may specify the functional operation of a desired circuit design using design and constraint entry tools 564. Design and constraint entry tools 564 may include tools such as design and constraint entry aid 566 and design editor 568. Design and constraint entry aids such as aid 566 may be used to help a circuit designer locate a desired design from a library of existing circuit designs and may provide computer-aided assistance to the circuit designer for entering (specifying) the desired circuit design.

As an example, design and constraint entry aid 566 may be used to present screens of options for a user. The user may click on on-screen options to select whether the circuit being designed should have certain features. Design editor 568 may be used to enter a design (e.g., by entering lines of hardware description language code), may be used to edit a design obtained from a library (e.g., using a design and constraint entry aid), or may assist a user in selecting and editing appropriate prepackaged code/designs.

Design and constraint entry tools 564 may be used to allow a circuit designer to provide a desired circuit design using any suitable format. For example, design and constraint entry tools 564 may include tools that allow the circuit designer to enter a circuit design using truth tables. Truth tables may be specified using text files or timing diagrams and may be imported from a library. Truth table circuit design and constraint entry may be used for a portion of a large circuit or for an entire circuit.

As another example, design and constraint entry tools 564 may include a schematic capture tool. A schematic capture tool may allow the circuit designer to visually construct integrated circuit designs from constituent parts such as logic gates and groups of logic gates. Libraries of preexisting integrated circuit designs may be used to allow a desired portion of a design to be imported with the schematic capture tools.

If desired, design and constraint entry tools 564 may allow the circuit designer to provide a circuit design to the circuit design system 400 using a hardware description language such as Verilog hardware description language (Verilog HDL), Very High Speed Integrated Circuit Hardware Description Language (VHDL), SystemVerilog, or a higher-level circuit description language such as OpenCL or SystemC, just to name a few. The designer of the integrated circuit design can enter the circuit design by writing hardware description language code with editor 568. Blocks of code may be imported from user-maintained or commercial libraries if desired.

After the design has been entered using design and constraint entry tools 564, behavioral simulation tools 572 may be used to simulate the functional performance of the circuit design. If the functional performance of the design is incomplete or incorrect, the circuit designer can make changes to the circuit design using design and constraint entry tools 564. The functional operation of the new circuit design may be verified using behavioral simulation tools 572 before synthesis operations have been performed using tools 574. Simulation tools such as behavioral simulation tools 572 may also be used at other stages in the design flow if desired (e.g., after logic synthesis). The output of the behavioral simulation tools 572 may be provided to the circuit designer in any suitable format (e.g., truth tables, timing diagrams, etc.).

Once the functional operation of the circuit design has been determined to be satisfactory, logic synthesis and optimization tools 574 may generate a gate-level netlist of the circuit design, for example using gates from a particular library pertaining to a targeted process supported by a foundry, which has been selected to produce the integrated circuit. Alternatively, logic synthesis and optimization tools 574 may generate a gate-level netlist of the circuit design using gates of a targeted programmable logic device (i.e., in the logic and interconnect resources of a particular programmable logic device product or product family).

Logic synthesis and optimization tools 574 may optimize the design by making appropriate selections of hardware to implement different logic functions in the circuit design based on the circuit design data and constraint data entered by the logic designer using tools 564. As an example, logic synthesis and optimization tools 574 may perform register retiming on the circuit design based on the length of a combinational path between registers in the circuit design and corresponding timing constraints that were entered by the logic designer using tools 564.

After logic synthesis and optimization using tools 574, the circuit design system may use tools such as placement and routing tools 576 to perform physical design steps (layout synthesis operations). Placement and routing tools 576 are used to determine where to place each gate of the gate-level netlist produced by tools 574. For example, if two counters interact with each other, the placement and routing tools 576 may locate these counters in adjacent regions to reduce interconnect delays or to satisfy timing requirements specifying the maximum permitted interconnect delay. The placement and routing tools 576 create orderly and efficient implementations of circuit designs for any targeted integrated circuit (e.g., for a given programmable integrated circuit such as a field-programmable gate array (FPGA)).

Tools such as tools 574 and 576 may be part of a compiler suite (e.g., part of a suite of compiler tools provided by a programmable logic device vendor). In certain embodiments, tools such as tools 574, 576, and 578 may also include timing analysis tools such as timing estimators. This allows tools 574 and 576 to satisfy performance requirements (e.g., timing requirements) before actually producing the integrated circuit.

After an implementation of the desired circuit design has been generated using placement and routing tools 576, the implementation of the design may be analyzed and tested using analysis tools 578. For example, analysis tools 578 may include timing analysis tools, power analysis tools, or formal verification tools, just to name few.

After satisfactory optimization operations have been completed using tools 520 and depending on the targeted integrated circuit technology, tools 520 may produce a mask-level layout description of the integrated circuit or configuration data for programming the programmable logic device.

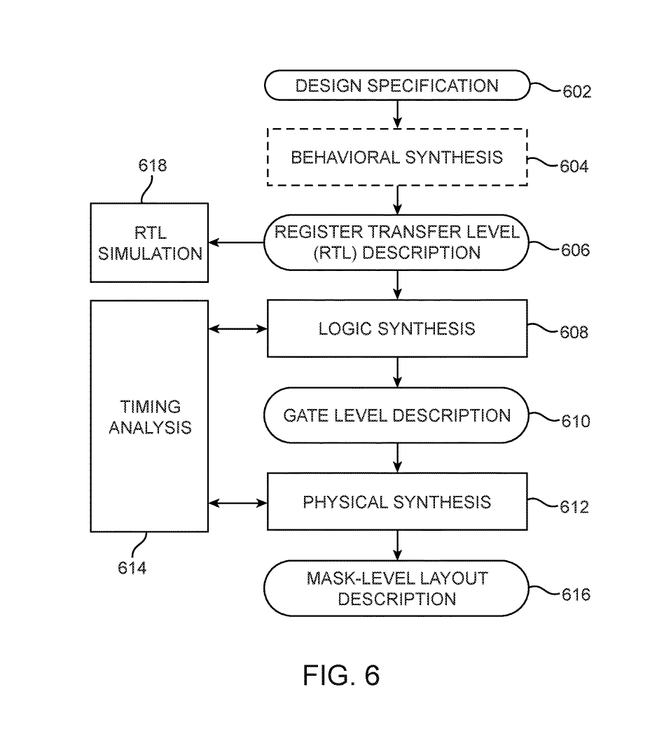

Illustrative operations involved in using tools 520 of FIG. 5 to produce the mask-level layout description of the integrated circuit are shown in FIG. 6. As shown in FIG. 6, a circuit designer may first provide a design specification 602. The design specification 602 may, in general, be a behavioral description provided in the form of an application code (e.g., C code, C++ code, SystemC code, OpenCL code, etc.). In some scenarios, the design specification may be provided in the form of a register transfer level (RTL) description 606.

The RTL description may have any form of describing circuit functions at the register transfer level. For example, the RTL description may be provided using a hardware description language such as the Verilog hardware description language (Verilog HDL or Verilog), the SystemVerilog hardware description language (SystemVerilog HDL or SystemVerilog), or the Very High Speed Integrated Circuit Hardware Description Language (VHDL). If desired, a portion or all of the RTL description may be provided as a schematic representation.

In general, the behavioral design specification 602 may include untimed or partially timed functional code (i.e., the application code does not describe cycle-by-cycle hardware behavior), whereas the RTL description 606 may include a fully timed design description that details the cycle-by-cycle behavior of the circuit at the register transfer level.

Design specification 602 or RTL description 606 may also include target criteria such as area use, power consumption, delay minimization, clock frequency optimization, or any combination thereof. The optimization constraints and target criteria may be collectively referred to as constraints.

Those constraints can be provided for individual data paths, portions of individual data paths, portions of a design, or for the entire design. For example, the constraints may be provided with the design specification 602, the RTL description 606 (e.g., as a pragma or as an assertion), in a constraint file, or through user input (e.g., using the design and constraint entry tools 564 of FIG. 5), to name a few.

At step 604, behavioral synthesis (sometimes also referred to as algorithmic synthesis) may be performed to convert the behavioral description into an RTL description 606. Step 604 may be skipped if the design specification is already provided in form of an RTL description.

At step 618, behavioral simulation tools 572 may perform an RTL simulation of the RTL description, which may verify the functional performance of the RTL description. If the functional performance of the RTL description is incomplete or incorrect, the circuit designer can make changes to the HDL code (as an example). During RTL simulation 618, actual results obtained from simulating the behavior of the RTL description may be compared with expected results.

During step 608, logic synthesis operations may generate gate-level description 610 using logic synthesis and optimization tools 574 from FIG. 5. If desired, logic synthesis operations may perform register retiming as illustrated in FIG. 2 according to the constraints that are included in design specification 602 or RTL description 606.

During step 612, physical synthesis operations (e.g., place and route and optimization operations using for example placement and routing tools 576) may place and connect the different gates in gate-level description 610 in a preferred location on the targeted integrated circuit to meet given target criteria (e.g., minimize area and maximize routing efficiency or minimize path delay and maximize clock frequency or any combination thereof).

If desired, physical synthesis operations may perform register retiming as illustrated in FIG. 2 and according to the constraints that are included in design specification 602 or RTL description 606. As an example, physical synthesis operations may perform register retiming by changing the configuration of some pipelined routing resources (e.g., some instances of pipelined routing resource 300 of FIG. 3) from operating in pipeline register mode to operating in non-pipelined mode and the configuration of other pipelined routing resources (e.g., other instances of pipelined routing resources 300 of FIG. 3) from operating in non-pipelined mode to operating in pipeline register mode. The output of physical synthesis 612 is a mask-level layout description 616.

The overall integrated circuit design flow described in connection with FIG. 6 can be dramatically simplified since the embedded BIST circuitry is able to easily meeting the timing requirements associated with the DSP block, which substantially reduces the complexity of the timing analysis step 614 in FIG. 6. In practice, the performance of all DSP blocks on an integrated circuit can be concurrently characterized using the embedded BIST circuitry.

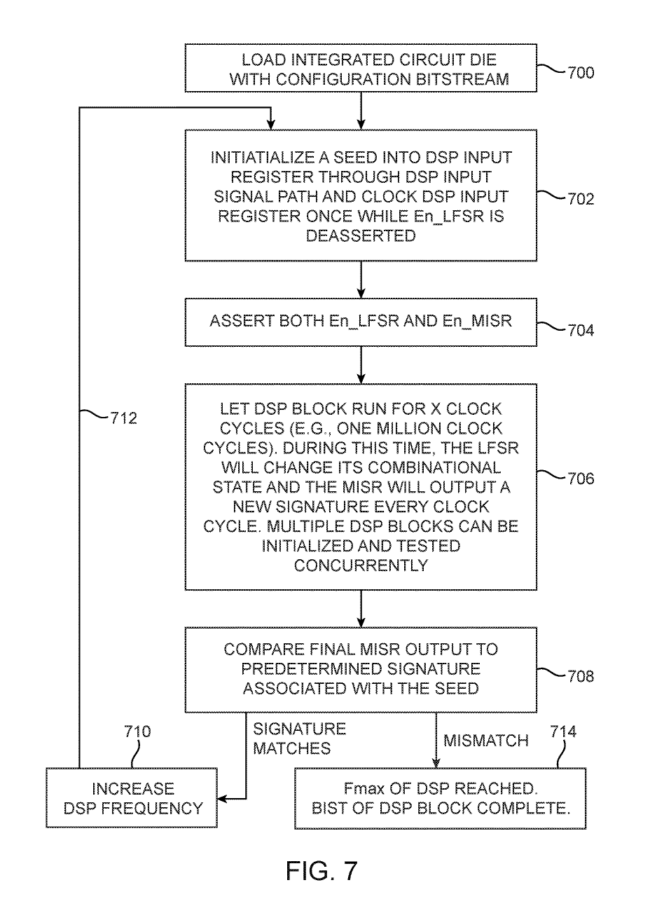

FIG. 7 is a flow chart of illustrative steps for performing validation on a specialized processing (DSP) block with embedded built-in self-test circuitry in accordance with an embodiment. At step 700, a configuration bit stream may be loaded into a programmable integrated circuit die, configuring the IC die to perform a custom user function.

At step 702, a seed may be injected into the DSP input registers through the DSP input signal path by clocking the input registers once while signal En_LFSR is deasserted. For example, an initializing seed value of “101011 . . . ” may be presented as parallel input bits to In1, In2, In3, . . . , InN, and these values may be latched by input registers 310.

At step 704, both control signals En_LFSR and En_MISR may be simultaneously asserted to enable the LFSR and the MISR built-in self-test functionality of the input and output registers.

At step 706, the DSP block may be allowed to run for X clock cycles (e.g., for a million clock cycles, a thousand clock cycles, for ten clock cycles, for one clock cycle, etc.) at a selected frequency. In the first iteration, the selected frequency may be relatively low to ensure that the DSP block performs as expected. During this time, circuit 302 configured as an LFSR will change its combinational state while circuit 304 configured as an MISR will output a new compressed signature every clock cycle. Circuits 302 and 304 and core DSP circuitry 300 are controlled by the same clock and therefore run at the same frequency. In general, more than one DSP blocks can be initialized and tested in parallel (e.g., the BIST circuitry in multiple DSP blocks may be enabled concurrently).

After X clock cycles has passed, the final compressed MISR output can be compared to a predetermined signature associated with the original seed value (step 708). The predetermined signature may represent a theoretical value that is pre-computed based on a properly functioning DSP block. If the signatures match, the operating frequency of the DSP block may be increased (step 710), and processing may loop back to step 702 for the next iteration (as indicated by path 712).

If the signatures no longer match, the maximum operating frequency (Fmax) of the DSP block will have been reached, and the BIST operation for that DSP block is complete (step 714). If desired, an Fmax value determined in this way can be correlated with other performance metrics such as the ring oscillator frequency on an integrated circuit and can therefore sometimes be used to bin the performance of integrated circuit dies.

The steps of FIG. 7 are merely illustrative. The existing steps may be modified or omitted; some of the steps may be performed in parallel; additional steps may be added; and the order of certain steps may be reversed or altered.

The embodiments thus far have been described with respect to integrated circuits. The methods and apparatuses described herein may be incorporated into any suitable circuit. For example, they may be incorporated into numerous types of devices such as programmable logic devices, application specific standard products (ASSPs), and application specific integrated circuits (ASICs). Examples of programmable logic devices include programmable arrays logic (PALs), programmable logic arrays (PLAs), field programmable logic arrays (FPGAs), electrically programmable logic devices (EPLDs), electrically erasable programmable logic devices (EEPLDs), logic cell arrays (LCAs), complex programmable logic devices (CPLDs), and field programmable gate arrays (FPGAs), just to name a few.

The programmable logic device described in one or more embodiments herein may be part of a data processing system that includes one or more of the following components: a processor; memory; IC circuitry; and peripheral devices. The data processing can be used in a wide variety of applications, such as computer networking, data networking, instrumentation, video processing, digital signal processing, or any suitable other application where the advantage of using programmable or re-programmable logic is desirable. The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system. In one embodiment, the programmable logic device may be one of the family of devices owned by ALTERA Corporation.

The foregoing is merely illustrative of the principles of this invention and various modifications can be made by those skilled in the art. The foregoing embodiments may be implemented individually or in any combination.

What is claimed is:

1. An integrated circuit die, comprising:
memory circuitry;
configurable logic circuitry; and
a specialized processing block that includes embedded built-in self-test circuitry.

2. The integrated circuit die of claim 1, wherein the specialized processing block comprises a digital signal processor (DSP) block.

3. The integrated circuit die of claim 1, wherein the embedded built-in self-test circuitry within the specialized processing block includes input registers coupled in a loop.

4. The integrated circuit die of claim 3, wherein the input registers of the specialized processing block are selectively enabled to operate as a linear feedback shift register.

5. The integrated circuit die of claim 4, wherein the specialized processing block further comprises:
a plurality of multiplexers interposed in the loop.

6. The integrated circuit die of claim 5, wherein each multiplexer in the plurality of multiplexers is controlled by a common enable signal.

7. The integrated circuit die of claim 4, wherein the specialized processing block further comprises:
a logic exclusive-OR gate interposed in the loop.

8. The integrated circuit die of claim 1, wherein the embedded built-in self-test circuitry within the specialized processing block includes output registers coupled in a chain.

9. The integrated circuit die of claim 8, wherein the output registers of the specialized processing block are selectively enabled to operate as a multiple input signature register.

10. The integrated circuit die of claim 9, wherein the specialized processing block further comprises:
a plurality of logic exclusive-OR gates interposed in the chain.

11. The integrated circuit die of claim 10, wherein the specialized processing block further comprises:
a plurality of multiplexers feeding the plurality of logic exclusive-OR gates.

12. The integrated circuit die of claim 11, wherein each multiplexer in the plurality of multiplexers has an input that receives a ground power supply voltage.

13. A method of operating an integrated circuit that includes memory circuitry and a specialized processing block, the method comprising:
with the memory circuitry, receiving a configuration bit stream;
with input registers embedded within the specialized processing block, performing built-in self-test (BIST) operations to validate the functionality of the specialized processing block; and
with output registers embedded within the specialized processing block, performing the built-in self-test (BIST) operations to validate the functionality of the specialized processing block.

14. The method of claim 13, wherein performing the BIST operations with the input registers comprises configuring the input registers in a linear feedback shift register mode, and wherein performing the BIST operations with the output registers comprises configuring the output registers in a multiple input signature register mode.

15. The method of claim 14, further comprising:
configuring the input registers using a first enable signal;
configuring the output registers using a second enable signal;
feeding a seed BIST value into the input registers while the first enable signal is deasserted; and
after latching the seed BIST value with the input register, asserting both the first and second enable signals.

16. The method of claim 15, further comprising:
after asserting the first and second enable signals, waiting for a predetermined time period; and
after waiting for the predetermined time period, comparing a signature generated by the output registers configured in the multiple input signature register mode to a pre-computed signature.

17. The method of claim 16, further comprising:
in response to determining that the signature generated by the output registers matches the pre-computed signature, increasing the frequency at which the specialized processing block is operated; and
in response to determining that the signature generated by the output registers does not match the pre-computed signature, terminating the BIST operations.

18. An integrated circuit die, comprising:
volatile memory;
soft logic; and
a digital signal processing block with embedded built-in self-test circuitry, wherein the built-in self-test circuitry is not implemented using any soft logic.

19. The integrated circuit die of claim 18, wherein the built-in self-test circuitry of the digital signal processing block is implemented using input registers and output registers within the digital signal processing block, and wherein the digital signal processing block includes internal processing circuitry that is coupled between the input registers and the output registers.

20. The integrated circuit die of claim 19, wherein the input registers are selectively enabled to operate as a linear feedback shift register, and wherein the output registers are selectively enabled to operate as a multiple input signature register.
